(19) United States
(12) Patent Application Publication
(10) Pub. No.: US 2023/0215670 A1
(43) Pub. Date: Jul. 6, 2023

(54) INPUT DEVICE

(71) Applicant: Panasonic Intellectual Property Management Co., Ltd., Osaka (JP)

(72) Inventors: Satoshi YOSHIHARA, Hyogo (JP); Kota ARAKI, Osaka (JP); Hiroaki NISHIONO, Osaka (JP); Kenji SHIBATA, Osaka (JP)

(21) Appl. No.: 17/913,093

(22) PCT Filed: Mar. 16, 2021
(86) PCT No.: PCT/JP2021/010663

§ 371 Date: Sep. 20, 2022

(30) Foreign Application Priority Data
Mar. 26, 2020 (JP) 2020-056654

(51) Int. Cl. H01H 25/00; G06F 3/044

(52) U.S. Cl. CPC H01H 25/00; G06F 3/044; H01H 2221/008

(57) ABSTRACT

An input device configured to more accurately detect movement of an operation part is provided. An input device includes a fixed electrode, a reference electrode, an operation part, and a moving electrode. The fixed electrode and the reference electrode are separate from each other on a substrate. The operation part is movable with respect to the substrate. The moving electrode faces the fixed electrode and is configured to move together with the operation part. The moving electrode 15 moves together with the operation part to enter either a connected state of being electrically connected to the reference electrode or a non-connected state of not being electrically connected to the reference electrode.

### TECHNICAL FIELD

The present disclosure relates to input devices. The present disclosure specifically relates to an input device configured to receive an input operation given by an operator.

### BACKGROUND ART

Patent Literature 1 describes a capacitive sensor (an input device) including: two substrates; a central electrode part, four electrode parts (fixed electrodes), a conductor (moving electrode), and an inputter (operation part). The two substrates are parallelly disposed to face each other, and one substrate of the two substrates is parallelly movable with respect to the other substrate of the two substrates. The central electrode part is disposed on a facing surface of the one substrate. The four electrode parts are arranged at 90° intervals around the central electrode part on the facing surface of the one substrate. The conductor is disposed on a facing surface of the other substrate. The inputter is provided on the other substrate. In this capacitive sensor, the movement (i.e., the magnitude of movement and the direction of movement) of the inputter is detected based on electrostatic capacitance between the conductor and each electrode part.

In the capacitive sensor described in Patent Literature 1, accurate detection of the movement of the inputter in a range of a small magnitude of movement of the inputter is not possible at the time of detecting the movement of the inputter due to the influence of dimensional variations or the like of the components of the capacitive sensor.

### CITATION LIST

### Patent Literature

Patent Literature 1: JP 3331385 B2

### SUMMARY OF INVENTION

In view of the foregoing, an object of the present disclosure is to provide an input device configured to more accurately detect movement of an operation part.

The input device of an aspect of the present disclosure includes a fixed electrode, a reference electrode, an operation part, and a moving electrode. The fixed electrode and the reference electrode are separate from each other on a substrate. The operation part is movable with respect to the substrate. The moving electrode faces the fixed electrode and is configured to be moved together with the operation part. The moving electrode is configured to move together with the operation part to enter either a connected state of being electrically connected to the reference electrode or a non-connected state of not being electrically connected to the reference electrode.

### BRIEF DESCRIPTION OF DRAWINGS

FIG. 1 is a perspective view of an input device according to a first embodiment;

FIG. 2 is an exploded perspective view of the input device;

FIG. 3 is a partially enlarged view of FIG. 2;

FIG. 4A is a sectional view taken along line X1-X1 of FIG. 1;

FIG. 4B is a partially enlarged view of FIG. 4A;

FIG. 4C is another partially enlarged view of FIG. 4A;

FIG. 5 is an explanatory view of a positional relationship between electrodes in a standby state of an operation knob;

FIG. 6A is a sectional view when a first-step slide operation is input to the operation knob;

FIG. 6B is a partially enlarged view of FIG. 6A;

FIG. 7 is an explanatory view of the positional relationship between the electrodes when the first-step slide operation is input to the operation knob;

FIG. 8 is an explanatory view illustrating a method of determining an operation direction of the operation knob;

FIG. 9A is a sectional view when a second-step slide operation is input to the operation knob;

FIG. 9B is a partially enlarged view of FIG. 9A;

FIG. 10 is an explanatory view of the positional relationship between the electrodes when the second-step slide operation is input to the operation knob;

FIG. 11 is an explanatory diagram of a relationship between the operation resistance of the operation knob and the position of the operation knob;

FIG. 12 is an explanatory view of electrodes of an input device according to a first variation of the first embodiment;

FIG. 13 is an exploded perspective view of a main part of an input device according to a second embodiment;

FIG. 14A is a sectional view when a first-step slide operation is input to an operation knob of the second embodiment;

FIG. 14B is a partially enlarged view of FIG. 14A;

FIG. 15 is an exploded perspective view of a main part of an input device according to a first variation of the second embodiment;

FIG. 16A is a sectional view when a first-step slide operation is input to an operation knob of the first variation of the second embodiment; and

FIG. 16B is a partially enlarged view of FIG. 16A.

### DESCRIPTION OF EMBODIMENTS

### 1. Embodiment 1

### 1-1. Overview

An input device 1 according to the present embodiment will be described in detail with reference to the drawings. The configuration described in this embodiment is only an example of the present disclosure. The present disclosure is not limited to the present embodiment, and various modifications may be made depending on design and the like without departing from the scope of the technical idea according to the present disclosure.

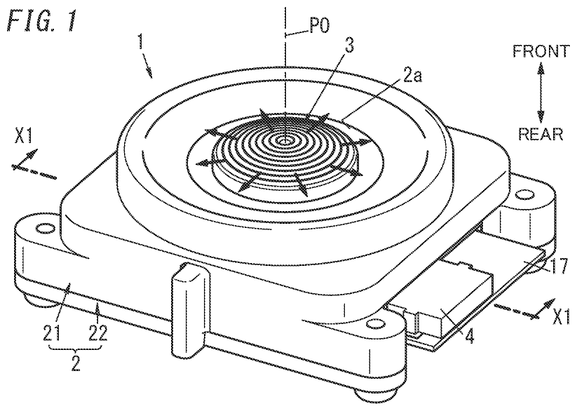

Referring to FIG. 1, the overview of the input device 1 will be described. As shown in FIG. 1, the input device 1 is a device for receiving an input operation given by an operator and is mountable on, for example, a spoke part of a steering wheel of an automobile or the like.

The input device 1 includes a housing 2, an operation knob 3 (operation part), and various components.

Here, in the present embodiment, one side on which the operating knob 3 is disposed is defined as the front side (front direction) of the input device 1, and the other side is defined as the rear side (rear direction) of the input device 1. However, defining the directions in this manner does not limit the function of the input device 1.

The housing 2 supports the operation knob 3 and houses and holds various components. The housing 2 is, for example, box-shaped and is rectangular in plan view. The housing 2 has an opening 2a in its front surface. The opening 2a is, for example, circular. The housing 2 includes a cover 21 and a rear panel 22.

The operation knob 3 is a part operated by an operator and has, for example, a flat columnar shape. The operation knob 3 is disposed in the opening 2a of the housing 2. The operation knob 3 is slidably movable within an opening surface of the opening 2a in response to an operation given by the operator. Note that slidably moving means moving along the opening surface of the opening 2a (i.e., along a sensor substrate 17 which is described later). Further, the operation knob 3 is linearly movable along the opening surface of the opening 2a. The operation knob 3 is movable in an arbitrary direction from a preset reference position P0 (e.g., a center position) within the opening surface (within a predetermined area) of the opening 2a in response to an operation given by the operator. When the operation is no longer given to the operation knob 3, the operation knob 3 autonomously returns to the reference position P0.

The operation of slidably moving the operation knob 3 may be hereinafter referred to as a slide operation. In addition, the state where the operation knob 3 is autonomously returned to and is at the reference position P0 is referred to as a standby state.

The various components include a member for movably supporting the operation knob 3 as described above, and the sensor substrate 17 configured to detect movement of the operation knob 3 (i.e., the operation given to the operation knob 3). Note that the movement of the operation knob 3 includes the direction of movement and the magnitude of movement of the operation knob 3. The sensor substrate 17 includes a connector 4 for outputting a result of the detection to the outside. That is, in the input device 1, the movement of the operation knob 3 is detected when a slide operation is given to the operation knob 3 by the operator, and the detection result is output from the connector 4 to the outside.

In the input device 1, the operation given to the operation knob 3 is detected in response to the movement of the operation knob 3 by a certain distance from the reference position P0. This prevents erroneous detection of the operation given to the operation knob 3 in a range of a small magnitude of movement of the operation knob 3. In the input device 1, when the operation given to the operation knob 3 is detected, the operation knob 3 is caused to generate a sense of click in order to inform the operator of the detection of the operation.

In addition, in the input device 1, when the slide operation is given to the operation knob 3, the operation given to the operation knob 3 is detected at each of two positions at which operation directions of the operation knob 3 are different. Thus, a series of slide operations given to the operation knob 3 can input two operations (i.e., two-step operation) to the operation knob 3. In the input device 1, each time each of the two operations is detected, the operation knob 3 is caused to generate a sense of click.

That is, when the operator gives a slide operation to the operation knob 3 to slide the operation knob 3 from the reference position P0 to a first detection position (position where a first-step slide operation is detected), the slide operation is detected, and the operator is provided with a sense of click by the operation knob 3. Then, the operator further gives a slide operation to the operation knob 3, thereby further slidably moving the operation knob 3 from the first detection position to a second detection position (position where a second-step slide operation is detected), and at this time, the slide operation is detected, and the operator is provided with a sense of click by the operation knob 3.

In the present embodiment, the first detection position is a position away from the reference position P0 by a first predetermined distance and is an arbitrary position on a circle around the reference position P0, the radius of the circle being the first predetermined distance. The second detection position is a position away from the reference position P0 by a second predetermined distance greater than the first predetermined distance and is an arbitrary position on a circle around the reference position P0, the radius of the circle being the second predetermined distance.

### 1-2. Configuration

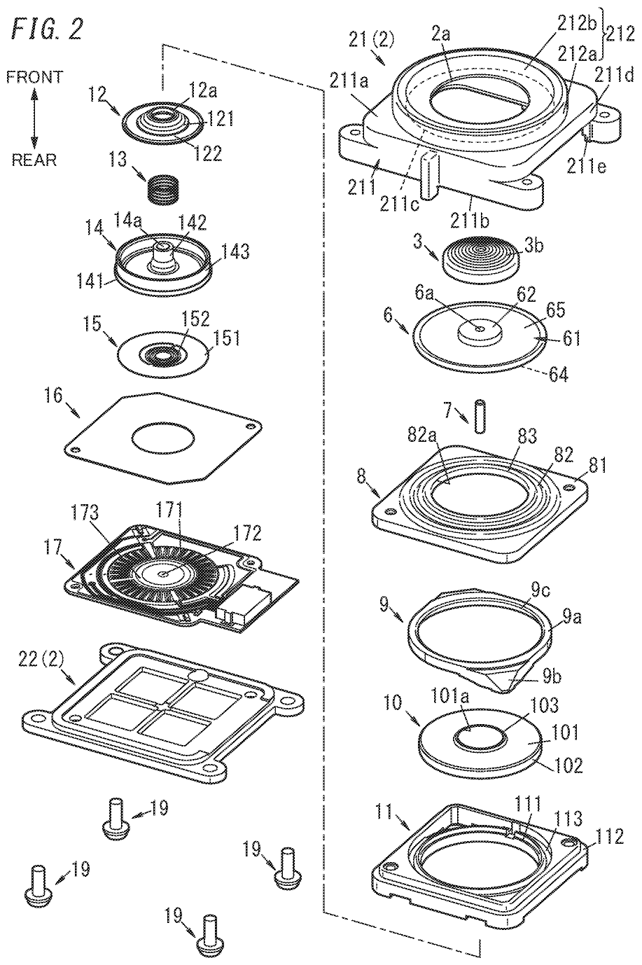

Referring to FIGS. 2 to 5, the configuration of the input device 1 will be described. As shown in FIG. 2, the input device 1 includes, in addition to the housing 2 and the operation knob 3, a slider 6, a shaft 7, a rubber mat 8, a light guide 9, a cover plate 10, a frame 11, a click cam 12, a return spring 13, a mover 14, a moving electrode 15, a dielectric film 16, the sensor substrate 17, the rear panel 22, and a plurality of (e.g., four) screws 19.

### Housing

As described above, the housing 2 includes the cover 21 and the rear panel 22.

The cover 21 houses and holds various components (e.g., the slider 6, the shaft 7, the rubber mat 8, the light guide 9, the cover plate 10, the frame 11, the click cam 12, the return spring 13, the mover 14, the moving electrode 15, the dielectric film 16, and the sensor substrate 17). The cover 21 is made of, for example, a resin.

The cover 21 includes a cover body 211 and a circular housing part 212. The cover body 211 has, for example, a rectangular parallelepiped box shape (in FIG. 2, a flat rectangular parallelepiped shape) and has a rear surface 211b which is open. More specifically, the cover 21 has a front surface 211a having an opening 211c which is circular. The cover body 211 has an outer peripheral surface 211d having a window 211e through which the sensor substrate 17 housed in the cover 21 is to partially protrude outward. The circular housing part 212 includes a cylindrical part 212a and a bottom 212b. The cylindrical part 212a protrudes, on the front surface 211a of the cover 21, frontward from a circumferential edge of the opening 211c. The bottom 212b is disposed at a front end of the cylindrical part 212a. The bottom 212b has the opening 2a which is circular. The circular housing part 212 has an internal space communicated with an internal space of the cover body 211 through the opening 211c of the cover body 211.

The rear panel 22 is a member which closes the rear surface 211b of the cover 21 with the various components being housed in the cover 21. The rear panel 23 has a flat plate shape of the same shape and size as the rear surface 211b of the cover 21. The rear panel 22 is made of, for example, a resin. The rear panel 22 is fixed to the rear surface 211b of the cover 21 by the four screws 19.

### Operation Knob

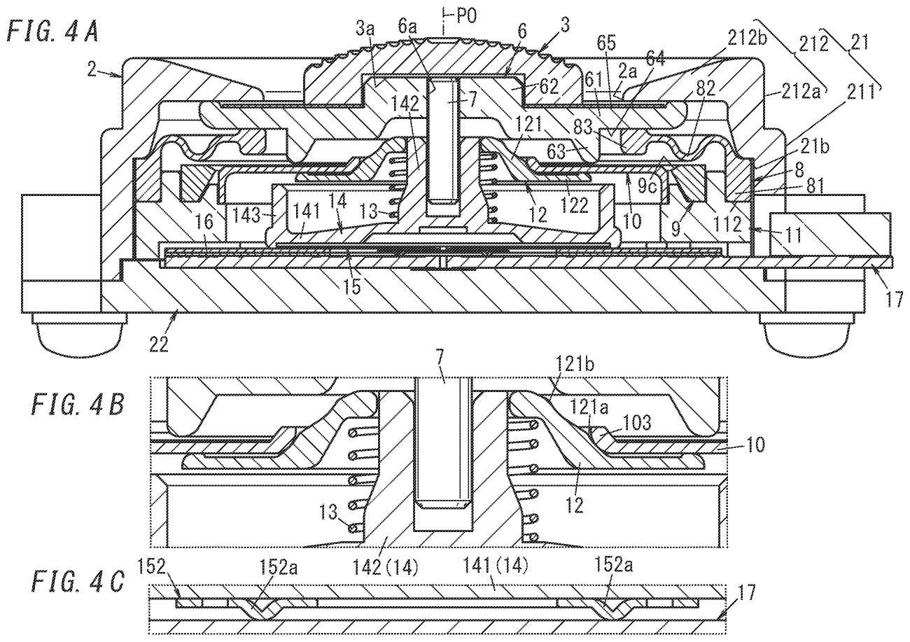

The operation knob 3 is a part operated by an operator. The operation knob 3 has, for example, a flat columnar shape. The operation knob 3 is fixed to a front surface of the slider 6. The operation knob 3 has a rear surface having a recess 3a (see FIG. 4), and fitting a boss 62 of the slider 6 in the recess 3a fixes the operation knob 3 to the front surface of the slider 6 (see FIG. 4). The boss 62 will be described later. The operation knob 3 is disposed in the opening 2a of the cover 21 so as to protrude frontward through the opening 2a (see FIG. 4). The operation knob 3 is slidably movable along the opening surface of the opening 2a (i.e., along the sensor substrate 17) within the opening surface of the opening 2a in response to an operation given by the operator. The operator brings, for example, his/her finger into contact with a front surface 3b of the operation knob 3, and in this state, the operator gives the slide operation to the operation knob 3.

### Slider

The slider 6 is a member that supports the operation knob 3 and moves together with the operation knob 3. The slider 6 has, for example, a substantially disk shape. More specifically, the slider 6 includes, for example, a slider body 61 and the boss 62. The slider body 61 has a circularly annular plate shape having a through hole 6a at the center thereof. The boss 62 is a part which is to be fit in the recess 3a of the operation knob 3 such that the boss 62 is connected to the operation knob 3. The boss 62 protrudes frontward from the center of a front surface of the slider body 61. The slider 6 has the through hole 6a to which the shaft 7 is fixed. The through hole 6a penetrates in the front-rear direction of the slider 6 at the center of the front surface of the slider 6.

The slider 6 is housed in the circular housing part 212 of the cover 21 (see FIG. 4). The slider 6 is made of a light-transmitting material (e.g., a resin). As shown in FIG. 4, the slider 6 has a sliding rib 63. The sliding rib 63 is disposed on a rear surface of the slider body 61 to have a circularly annular shape centered on the through hole 6a and protrudes backward. As the housed state described above, the slider 6 is disposed on a back side of the opening 2a of the housing 2 and is sandwiched between the bottom 212b of the circular housing part 212 of the housing 2 and the cover plate 10 (see FIG. 4). Specifically, the sliding rib 63 abuts on a front surface of the cover plate 10, and the slider 6 is housed so as to be movable by being slide on the front surface of the cover plate 10. This movement of the slider 6 is restricted by an inner circumferential surface of the circular housing part 212 (i.e., inner circumferential surface of the cylindrical part 212a).

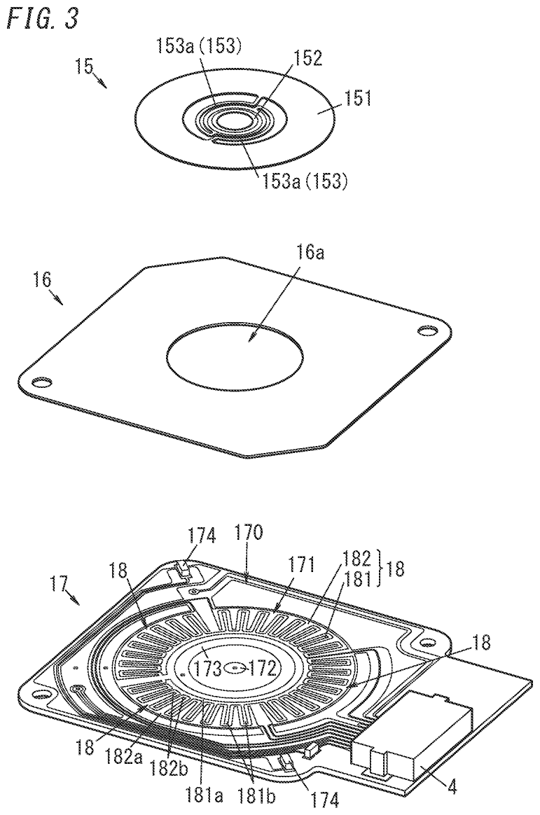

The slider 6 further includes a light incident part 64 and a light emitting part 65. The light incident part 64 is constituted by an outer circumferential surface of the sliding rib 63 and the rear surface of the slider body 61 on an outer side of the sliding rib 63. The light emitting part 65 is constituted by the front surface of the slider body 61. The slider 6 is configured such that light from light sources 174 (see FIG. 3) disposed on the sensor substrate 17 is incident on the light incident part 64 through the light guide 9 and is emitted from the light emitting part 65. Thus, the light from the light sources 174 is radiated to the outside through a gap (see FIG. 1) between the operation knob 3 and the edge, defining the opening 2a, of the housing 2, so that light is emitted in a ring shape at the gap.

### Shaft

The shaft 7 is a component which connects the slider 6 and the mover 14 to each other. The shaft 7 has, for example, a columnar shape. The shaft 7 has a front end part inserted into and fixed to the through hole 6a of the slider 6, and the shaft 7 has a rear end part inserted into a through hole 14a of the mover 14. The through hole 14a will be described later.

### Rubber Mat

The rubber mat 8 is a member which prevents dust entered through the opening 2a of the housing 2 from further entering in the housing 2, and the rubber mat 8 is formed of an elastic member having rubber elasticity. The rubber mat 8 is disposed between the frame 11 and a set of the cover 21 and the slider 6 (see FIG. 4).

The rubber mat 8 includes a frame 81, a bellows part 82, and a rib 83. The frame 81 is a part which supports the bellows part 82 and which is to be fixed to the housing 2. The frame 81 has, for example, a frame shape having a rectangular exterior and having a circular inner hole. The frame 81 is fixed by being sandwiched between a step part 21b of an inner peripheral surface of the cover 21 and an outer step part 112 of the frame 11 (see FIG. 4). The outer step part 112 will be described later. The bellows part 82 has a circularly annular shape having an opening 82a at the center thereof and has a bellows shape bent along the radial direction. The bellows part 82 has an outer circumference connected to the frame 81. The rib 83 is a part which is pressed against a circumferential edge of a rear surface of the slider 6 by the elasticity of (e.g., by being lightly urged by) the bellows part 82. The rib 83 is provided annularly along the entire inner circumferential end of the bellows part 82 and protrudes frontward.

### Light Guide

The light guide 9 is a component which guides light from the light sources 174 disposed on the sensor substrate 17 to the slider 6. The light guide 9 has, for example, a circularly annular shape and is made of a light-transmitting material (e.g., a resin). The light guide 9 is fixed to a front surface of the frame 11 (see FIG. 4). In this fixed state, the light guide 9 is disposed on the back side of the rubber mat 8 (more specifically, the bellows part 82) (see FIG. 4).

The light guide 9 includes a light guide body 9a, a light incident part 9b, and a light emitting part 9c. The light guide body 9a has, for example, a circular ring shape. The light incident part 9b is a part on which light from the light sources 174 is incident. The light incident part 9b protrudes outward from an outer circumferential surface of the light guide body 9a and is disposed in front of the light sources 174. The light emitting part 9c is a part from which light incident on the light incident part 9b and propagated through the light guide body 9a are emitted outside. The light emitting part 9c is constituted by a chamfered surface between a front surface and an inner circumferential surface of the light guide body 9a. The light emitted from the light emitting part 9c passes between the bellows part 82 of the rubber mat 8 and the cover plate 10 and is incident on the light incident part 64 of the slider 6 (see FIG. 4).

### Covering Plate

The cover plate 10 is a component which supports the slider 6 so as to be slidably movable. The cover plate 10 is fixed to the frame 11 and is disposed on the back side of the slider 6 (see FIG. 4). The cover plate 10 is made of metal, for example, and has a substantially disk shape, for example. The cover plate 10 includes a substrate part 101, a peripheral wall 102, and a contact part 103. The substrate part 101 has an annular plate shape (e.g., a circularly annular plate shape) having an opening 101a at the center thereof. The opening 101a is, for example, circular. The substrate part 101 has a front surface which is smooth and which constitutes a sliding surface on which the slider 6 is moved by being slid. The peripheral wall 102 is a part which is to be fixed to the frame 11. The peripheral wall 102 is provided annularly along the entire circumferential edge of a rear surface of the substrate part 101 and protrudes backward. The contact part 103 is a part which comes into contact with a cam surface of the click cam 12. The contact part 103 is provided annularly along the entire inner circumferential end of the substrate part 101. The contact part 103 is curved so as to protrude frontward toward the inside of the contact part 103.

### Frame

The frame 11 is a component to which the rubber mat 8, the light guide 9, and the cover plate 10 are to be fixed. The frame 11 has, for example, an annular plate shape having a rectangular exterior and having a circular inner hole and is made of, for example, a resin. The front surface of the frame 11 includes an inner step part 111, an outer step part 112, and a recess 113. The inner step part 111 is a part to which the peripheral wall 102 of the cover plate 10 is to be fitted. The inner step part 111 has a concave shape formed along the entire inner circumferential edge of the front surface of the frame 11. The outer step part 112 is a part to which the frame 81 of the rubber mat 8 is to be fitted. The outer step part 112 has a concave shape formed along the entire outer peripheral edge of the front surface of the frame 11. The recess 113 is a part to which a rear part of the light guide 9 is to be fitted. The recess 113 has a concave shape formed along the entire circumference of the frame 11 between the inner step part 111 and the outer step part 112 on the front surface of the frame 11.

### Click Cam

The click cam 12 is a component which generates a sense of click when the slide operation is given to the operation knob 3. The click cam 12 has a substantially plate-like annular shape (substantially circularly annular shape in FIG. 2) having an opening 12a at the center thereof. The click cam 12 is made of metal. The click cam 12 includes a cam part 121 and an outer circumferential edge part 122. The cam part 121 is a part with which the contact part 103 of the cover plate 10 comes into contact. The cam part 121 has a substantially tapered conical shape. The cam part 121 has a front end having an opening, and the opening constitutes the opening 12a. The outer diameter at a front surface side contacting a rear end of the cam part 121 (i.e., the diameter at the rear end of an outer circumferential surface of the cam part 121) is substantially equal to the diameter of the opening 101a of the cover plate 10. As a result, the cam part 121 is arranged concentrically with the opening 101a with the entirety of the cam part 121 protruding frontward and straightly through the opening 102a of the cover plate 10.

The outer circumferential surface (i.e., a cam surface) of the cam part 121 has two click ridges (a first click ridge 121a and a second click ridge 121b) (see FIG. 4B). The two click ridges 121a and 121b are provided so as to be shifted from each other in the front-rear direction along the outer circumferential surface of the cam part 121 and are annularly provided along the entire circumference of the cam part 121. On the cam surface of the cam part 121, the first click ridge 121a is provided closer to the rear end of the cam part 121 than the second click ridge 121b is. When the contact part 103 of the cover plate 10 climbs over the click ridges 121a and 121b, a sense of click is generated by the click cam 12 (and thus, by the operation knob 3). The outer circumferential edge part 122 is a part which hooks on the rear surface of the substrate part 101 of the cover plate 10. The outer circumferential edge part 122 is formed to have an annular shape formed along the entire circumference of the rear end of the cam part 121 and protrudes on a circumferentially outside.

The click cam 12 is disposed between the cover plate 10 and the mover 14 (see FIG. 4A). In this arrangement state, a boss 142 of the mover 14 is inserted into the opening 12a of the click cam 12. The boss 142 will be described later. The cam part 121 protrudes from the opening 101a of the cover plate 10 to the front of the cover plate 10. The contact part 103 of the cover plate 10 is in contact with the outer circumferential surface of the cam part 121. The outer circumferential edge part 122 is disposed at the side of the rear surface of the cover plate 10. The click cam 12 is movable in the front-rear direction along the boss 142 and is swingable with respect to the boss 142.

### Return Spring

The return spring 13 is a component for autonomously returning the operation knob 3 to the reference position P0 (see FIG. 1). The return spring 13 is, for example, a coil spring. The return spring 13 is disposed on the outer circumference of the boss 142 of the mover 14, and in this state, the return spring 13 is compressed by being sandwiched between the click cam 12 and a bottom 141 of the mover 14. The boss 142 and the bottom 141 will be described later. The return spring 13 urges the click cam 12 frontward and the mover 14 backward by its compressive repulsive force. The return spring 13 urges the click cam 12 frontward, thereby causing the cam part 121 of the click cam 12 to protrude frontward and straightly from the opening 101a of the cover plate 10. Thus, the operation knob 3 autonomously returns to the reference position P0. That is, the moving electrode 15 autonomously returns to the reference position P0.

### Mover

The mover 14 is a component to which the moving electrode 15 is fixed and which swingably holds the click cam 12. The mover 14 is made of, for example, a resin. As described above, the mover 14 is connected to the operation knob 3 via the shaft 7 and the slider 6. Thus, the mover 14 slidably moves the moving electrode 15 in response to the slide operation given to the operation knob 3. The mover 14 has a bottom 141, the boss 142, and a peripheral wall 143. The bottom 141 has, for example, a circular plate shape. The moving electrode 15 is fixed to a rear surface of the bottom 141. The boss 142 is a part which holds the click cam 12 such that the click cam 12 is swingable as described above. The boss 142 protrudes frontward from the center of a front surface of the bottom 141 to have a columnar shape. The peripheral wall 143 is provided along the entire outer circumferential edge of the front surface of the bottom 141 and protrudes frontward.

### Moving Electrode

The moving electrode 15 is an electrode fixed to a rear surface of the mover 14 so as to move together with the operation knob 3 in response to the slide operation given to the operation knob 3. The moving electrode 15 moves together with the operation knob 3, and thereby, the moving electrode 15 contacts and separates from (i.e., comes into, and out of, contact with) two electrodes (a reference electrode 172 and a switching electrode 173) which are described later. Based on this contact/separation, whether or not the first stage operation is given to the operation knob 3, and whether or not the second stage operation is given to the operation knob 3 are detectable. Further, the capacitance of the fixed electrode 171 changes depending on a relative arrangement of the moving electrode 15 and the fixed electrode 171 (more specifically, each of split electrodes 18), based on this change, the operation direction of the operation knob 3 is detectable. The fixed electrode 171 will be described later. Note that the operation direction of the operation knob 3 is the direction of movement of the operation knob 3 (i.e., the direction of movement of the moving electrode 15).

The moving electrode 15 is made of metal, for example, and has a substantially disk shape, for example. The moving electrode 15 includes a moving electrode body 151, a terminal 152, and a leaf spring 153 (see FIG. 3).

The moving electrode body 151 is an electrode which changes the capacitance of the fixed electrode 171 depending on the relative arrangement with respect to the fixed electrode 171. The fixed electrode 171 will be described later. The moving electrode body 151 has, for example, a circularly annular plate shape. The moving electrode body 151 is pressed against a front surface of the dielectric film 16 by being urged by the return spring 13. The dielectric film 16 will be described later. Thus, the moving electrode body 151 faces the fixed electrode 171 while maintaining the thickness of the dielectric film 16. In this facing state, the moving electrode body 151 is slidably movable on the front surface of the dielectric film 16.

The terminal 152 is a part which contacts and separates from the reference electrode 172 and the switching electrode 173 of the sensor substrate 17. The reference electrode 172 and the switching electrode 173 will be described later. The terminal 152 has, for example, a circularly annular plate shape and is arranged concentrically with the moving electrode main body 151 on an inner side of the moving electrode main body 151. The terminal 152 has a lower surface having a protrusion 152a for contacting the reference electrode 172 and the switching electrode 173 (see FIG. 4C). The protrusion 152a is annularly provided along the entire circumference of a rear surface of the terminal 152 and protrudes backward.

The leaf spring 153 is a part which elastically connects the moving electrode body 151 and the terminal 152 to each other. The leaf spring 153 urges the terminal 152 toward the sensor substrate 17. Thus, the terminal 152 is brought into contact with the reference electrode 172 and the switching electrode 173 of the sensor substrate 17. The leaf spring 153 has a plurality of (e.g., two) arms 153a. Each of the arms 153a is curved in an arc shape along the outer circumference of the terminal 152 from an inner circumferential end of the moving electrode body 151 and is connected to an outer circumferential end of the terminal 152.

### Dielectric Film

The dielectric film 16 is made of a dielectric material (e.g., a resin such as polycarbonate and polyester). The dielectric film 16 has, for example, a substantially rectangular sheet shape having an opening 16a which is, for example, circular. The dielectric film 16 is disposed between the moving electrode 15 and the sensor substrate 17. In this arrangement state, the dielectric film 16 covers the fixed electrode 171 of the sensor substrate 17 and exposes the reference electrode 172 and the switching electrode 173 of the sensor substrate 17 from the opening 16a. The fixed electrode 171, the reference electrode 172, and the switching electrode 173 will be described later.

### Sensor Substrate

The sensor substrate 17 is a circuit board configured to detect movement of the moving electrode 15. The sensor substrate 17 includes a substrate body 170, various electrodes (the fixed electrode 171, the switching electrode 173, and the reference electrode 172), one or more (e.g., two) light sources 174, and the connector 4.

The substrate body 170 is, for example, a printed circuit board made of a glass-containing epoxy resin. The substrate body 170 has a front surface provided with the various electrodes, the light sources 174, and the connector 4.

The reference electrode 172 is a part which contacts and separates from the terminal 152 of the moving electrode 15. Based on this contact/separation, whether or not the first stage operation is given to the operation knob 3 (i.e., whether or not the operation knob 3 is moved by the first predetermined distance from the reference position P0) is detectable. The reference electrode 172 is made of metal, for example, and has a disk shape, for example. The reference electrode 172 is connected to a terminal of the connector 4 via a line. The reference electrode 172 is connected to the reference potential (e.g., ground potential) by an external control circuit connected to the connector 4.

The fixed electrode 171 is an electrode whose capacitance varies depending on the relative arrangement with respect to the moving electrode body 151 (more specifically, the area overlapping the moving electrode body 151 when viewed in the front-rear direction of the input device 1). The capacitance of the fixed electrode 171 itself is the amount of electric charge stored in the fixed electrode 171. The fixed electrode 171 has, for example, a circularly annular shape. The fixed electrode 171 is disposed concentrically with the reference electrode 172 on an outer circumferential side of the reference electrode 172.

The fixed electrode 171 includes the plurality of (e.g., four) split electrodes 18 arranged in an annular (e.g., circular) shape. Each split electrode 18 has a fan shape obtained by splitting the fixed electrode 171 into four equal parts in 90° increments in the circumferential direction.

More specifically, each split electrode 18 includes a drive electrode 181 and a receiving electrode 182. The drive electrode 181 constitutes an inner circumferential side part of the fixed electrode 171, and the receiving electrode 182 constitutes an outer circumferential side part of the fixed electrode 171. The drive electrode 181 includes a first coupler 181a and a plurality of first comb teeth 181b. The first coupler 181a has an arc strip shape. The plurality of first comb teeth 181b are arranged at an outer circumferential end of the first coupler 181a at equal intervals along the outer circumferential end and protrude to an outer side of the fixed electrode 171. The receiving electrode 182 includes a second coupler 182a and a plurality of second comb teeth 182b. The second coupler 182a has an arc strip shape. The plurality of second comb teeth 182b are arranged at an inner circumferential end of the second coupler 182a at equal intervals along the inner circumferential end and protrude to an inner side of the fixed electrode 171. Each of the plurality of first comb teeth 181b is disposed between the plurality of second comb teeth 182b.

The capacitance of each split electrode 18 is the amount of electric charge stored between the drive electrode 181 and the receiving electrode 182. The capacitance of each split electrode 18 individually varies depending on the relative arrangement of each split electrode 18 and the moving electrode 15 (more specifically, the size of the area of each split electrode 18 overlapping the moving electrode 15 when viewed in the front-rear direction of the input device 1). Based on the capacitance of each split electrode 18, the direction of movement of the moving electrode 15 (i.e., the direction of movement of the operation knob 3) is detectable.

The receiving electrodes 182 of the split electrodes 18 are connected to different terminals in the connector 4 via different lines. The drive electrodes 181 of the split electrodes 18 are connected to each other to constitute one drive electrode. The drive electrodes thus connected are connected to the terminal of the connector 4 via a common line.

The switching electrode 173 is a part which contacts and separates from the terminal 152 of the moving electrode 15. Based on this contact/separation, whether or not the second stage operation is given to the operation knob 3 is detectable. The switching electrode 173 is made of metal, for example, and has a circularly annular shape, for example. The switching electrode 173 is arranged concentrically with the fixed electrode 171 between the reference electrode 172 and the fixed electrode 171. The switching electrode 173 is connected to a terminal of the connector 4 via a line.

The two light sources 174 are light sources for emitting light at the gap between the operation knob 3 and the edge, defining the opening 2a, of the housing 2. Each light source 174 is, for example, a light emitting diode (LED) and is disposed at a predetermined position on the front surface of the substrate body 170. Each light source 174 is connected to a terminal of the connector 4 via a line.

The connector 4 is a component for connecting to an external control circuit via, for example, a cable. The connector 4 includes a plurality of terminals. To the plurality of terminals, a line from each receiving electrode 182, a line from the drive electrodes 181 thus connected, a line from the reference electrode 172, a line from the switching electrode 173, and a line from each light source 174 are connected. The connector 4 enables information to be output to the outside. Examples of the information include the capacitance of each split electrode 18 and the potential of the switching electrode 173. Further, the connector 4 enables the potential of the reference electrode 172 to be externally controlled to the reference potential or lighting of each light source 174 to be externally controlled.

In the present embodiment, the terminal 152 of the moving electrode 15 and the reference electrode 172 constitute a contact/separation part that brings the moving electrode 15 into, and out of, electrical contact with the reference electrode 172. The click cam 12 and the cover plate 10 constitute a first click sense generator and a second click sense generator. The first click sense generator causes the operation knob 3 to generate a sense of click when the state of the moving electrode 15 changes from a state of not being in contact with the reference electrode 172 (first non-connected state) to a state of being in contact with the reference electrode 172 (first connected state). The second click sense generator causes the operation knob 3 to generate a sense of click when the state of the moving electrode 15 changes from a state of not being in contact with the switching electrode 173 (second non-connected state) to a state of being in contact with the switching electrode 173 (second connected state).

In the input device 1 having such a configuration, the operating knob 3 is slidably movable relative to the sensor substrate 17. The operation knob 3, the slider 6, the mover 14, and the moving electrode 15 are integrally connected to one another. The moving electrode 15 is pressed against the front surface of the dielectric film 16 by the return spring 13. As a result, the distance between the moving electrode 15 and the fixed electrode 171 is kept at a constant distance (i.e., the thickness of the dielectric film 16).

When a slide operation is given to the operation knob 3, the moving electrode 15 moves (slidably moves) in parallel keeping a constant distance from the fixed electrode 171. This movement brings the terminal 152 of the moving electrode 15 into, and out of, contact with the reference electrode 172. Further, this movement changes the relative arrangement between the moving electrode 15 and each split electrode 18, thereby changing the capacitance of each split electrode 18. Then, when a further slide operation is given to the operation knob 3, the moving electrode 15 further slidably moves. This further movement brings the terminal 152 into, and out of, contact with the switching electrode 173.

Further, the mover 14 moves in response to the slide operations given to the operation knob 3. With this movement, the click cam 12 is tilted with respect to the boss 142 of the mover 14, thereby moving to the back of the cover plate 10. At this time, the contact part 103 of the cover plate 10 is moved by being slid on the cam surface (outer circumferential surface) of the click cam 12.

Further, in the input device 1 configured as described above, the external control circuit connected to the connector 4 detects, based on the output signal of the connector 4, whether or not the first stage operation is input to the operation knob 3, the operation direction of the operation knob 3, and whether or not the second stage operation is input to the operation knob 3.

### 1-3. Operation Description

Next, the operation of the input device 1 will be described.

### Standby State

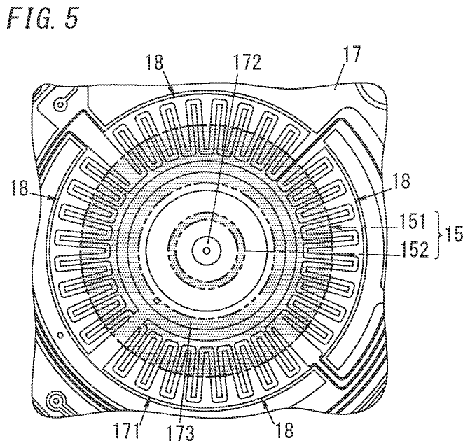

First, referring to FIGS. 4A, 4B, and 5, the positional relationship of the main parts of the input device 1 will be described when the operating knob 3 is in the standby state. Note that the standby state of the operation knob 3 is a state where the operation given to the operation knob 3 is released and the operation knob 3 (and thus, the moving electrode 15) is autonomously returned to and is at the reference position P0.

In the standby state of the operation knob 3, as shown in FIG. 4A, the operation knob 3 is disposed at the reference position P0 (e.g., the center position) of the opening surface of the opening 2a of the housing 2. In this state, the return spring 13 urges the cam part 121 such that the cam part 121 protrudes frontward and straightly from the opening 102a until the rear end of the cam part 121 of the click cam 12 fits into the opening 102a of the cover plate 10. The rear end of the cam part 121 is fit into the opening 102a of the cover plate 10, and thereby, the center of the cam part 121 coincides with the center (i.e., the reference position P0) of the opening 102a. Thus, the operation knob 3 is disposed at the reference position P0.

In the standby state of the operating knob 3, as shown in FIG. 4B, the contact part 103 of the cover plate 10 is positioned at a back side of the first click ridge 121a while being in contact with the cam surface (outer circumferential surface) of the cam part 121.

Further, in the standby state of the operation knob 3 (i.e., when the moving electrode 15 is positioned at the reference position P0), the terminal 152 of the moving electrode 15 is disposed between the reference electrode 172 and the switching electrode 173 in a plan view as viewed in the longitudinal direction (i.e., the normal direction to the sensor substrate 17) as shown in FIG. 5. In this arrangement state, the terminal 152 (and thus, the moving electrode 15) is in a state of not being in contact with the reference electrode 172 (first non-contact state), and a state of not being in contact with the switching electrode 173 (second non-contact state). Therefore, the movement of the moving electrode 15 is not detected. As described above, the reference position P0 in the present embodiment is a dead zone in which the movement of the moving electrode 15 is not detected. The moving electrode body 151 is arranged concentrically with the fixed electrode 171 and evenly overlaps each of the split electrodes 18.

Further, the operation knob 3 can be moved from the standby state in any direction from a current position (reference position P0 in the standby state) along the sensor substrate 17. In other words, the moving electrode 15 is movable from the current position in any direction along the sensor substrate 17. Further, the operation knob 3 is linearly movable from the standby state along the sensor substrate 17. In other words, the moving electrode 15 is linearly movable along the sensor substrate 17.

### Operation for Inputting First-Step Slide Operation

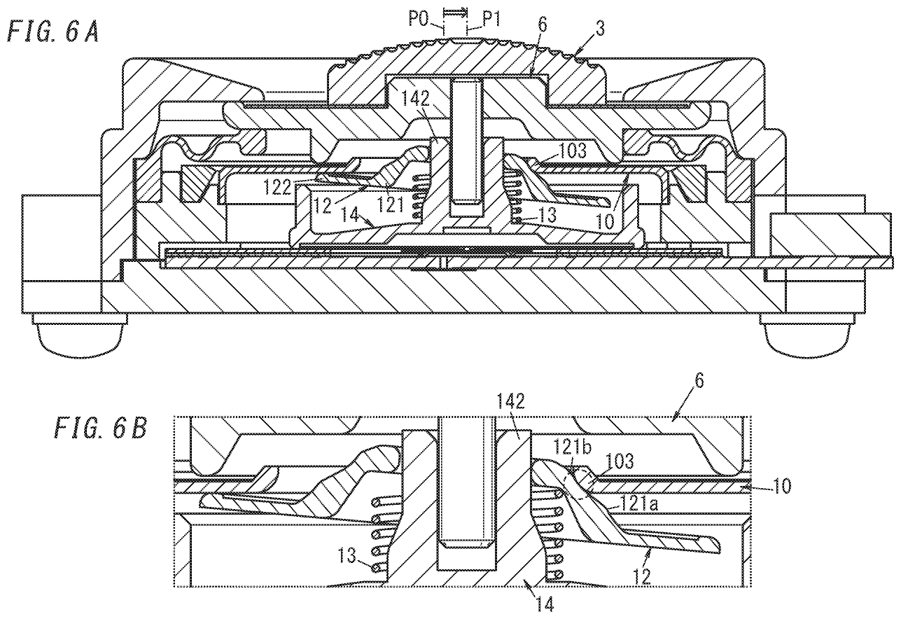

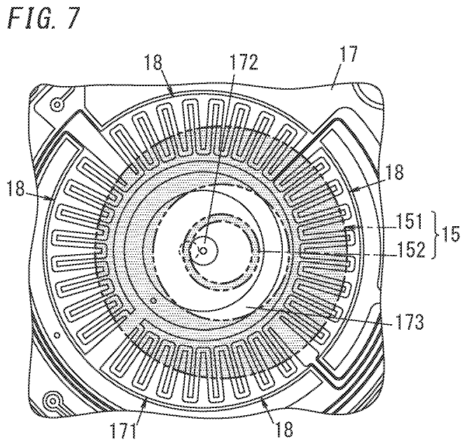

Next, referring to FIGS. 6A, 6B, and 7, operation when the first-step slide operation is input to the operation knob 3 will be described. The first-step slide operation is an operation of slidably moving the operation knob 3 from the reference position P0 to a first detection position P1.

As shown in FIG. 6A, in response to the slide operation of sliding the operation knob 3 from the reference position P0 to the first detection position P1, the mover 14 moves in the same direction as a direction in which the operation knob 3 is moved. With this movement, the cam part 121 of the click cam 12 is tilted with respect to the boss 142 of the mover 14, thereby moving to the back of the cover plate 10.

At this time, as shown in FIG. 6B, the contacting portion 103 of the cover plate 10 slides on the cam surface of the cam part 121 to climb over the first click ridge 121a and is disposed between the two click ridges (i.e., the first click ridge 121a and the second click ridge 121b). The contact part 103 increases the operation resistance against the slide operation until the contact part 102 climbs over the first click ridge 121a, and once the contact part 103 climbs over the first click ridge 121a, the contact part 103 then reduces the operation resistance. Due to a change in increasing/reducing the operation resistance, a sense of click is generated by the operation knob 3. Thus, in response to the slide operation of sliding the operation knob 3 from the reference position P0 to the first detection position P1 (i.e., when the state of the moving electrode 15 changes from the first non-contact state to the first contact state as described later), a sense of click is generated in synchronization with the slide operation.

Further, as shown in FIG. 7, when a slide operation is given to slidably move the operation knob 3 from the reference position P0 to the first detection position P1, the terminal 152 of the moving electrode 15 comes into contact with the reference electrode 172. That is, the state of the moving electrode 15 changes from a state of not being in contact with the reference electrode 172 (first non-contact state) to a state of being in contact with the reference electrode 172 (first contact state). After the state of the moving electrode 15 changes from the first non-contact state to the first contact state, the terminal 152 is not yet in contact with the switching electrode 173. That is, the terminal 152 is in a state of not being in contact with the switching electrode 173 (second non-contact state). The external control circuit connected to the connector 4 detects that the state of the moving electrode 15 has been changed from the first non-contact state to the first contact state, and thereby, detecting that the slide operation of sliding the operation knob 3 from the reference position P0 to the first detection position P1 has been conducted (that the first-step slide operation has been input to the operation knob 3). Further, the external control circuit detects the operation direction of the slide operation from the capacitance of each of the split electrodes 18.

Note that the external control circuit detects that the state of the moving electrode 15 has changed from the first non-contact state to the first contact state (that is, the first-step slide operation is input to the operation knob 3) as described below. That is, the external control circuit keeps the potential of the reference electrode 172 at a reference potential and detects the capacitance of each split electrode 18 via the connector 4. In a state where the terminal 152 of the moving electrode 15 is not in contact with the reference electrode 172 (first non-contact state), the moving electrode 15 enters in a floating state where the potential there of is independent, and the moving electrode 15 does thus not change the capacitance of each split electrode 18. However, in a state where the terminal 152 is in contact with the reference electrode 172 (the first contact state), the moving electrode 15 reaches the reference potential, and therefore, the capacitance of each split electrode 18 changes depending on the relative arrangement of each split electrode 18 and the moving electrode body 151. For example, as the size of the area of each split electrode 18 overlapping the moving electrode body 151 increases, the capacitance of each split electrode 18 decreases. Thus, when the state of the moving electrode 15 changes from the first non-connected state to the first connected state, the capacitance of each split electrode 18 changes. The external control circuit detects this change, thereby detecting that the state of the moving electrode 15 has changed from the first non-contact state to the first contact state.

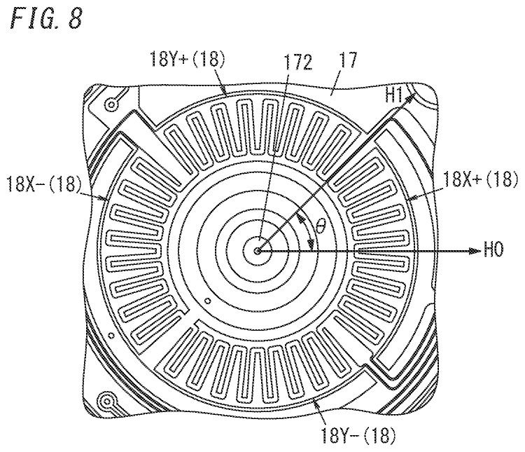

Further, the external control circuit detects an operation direction H1 of the slide operation as described below. Here, as shown in FIG. 8, the four split electrodes 18 are distinguished from one another as a split electrodes 18X+, a split electrodes 18X−, a split electrodes 18Y+, and a split electrodes 18Y−. The capacitances of the split electrodes 18X+, 18X−, 18Y+, and 18Y− are respectively defined as C(X+), C(X−), C(Y+), and C(Y−). Further, the reference azimuth H0 is defined as, for example, the right direction of the paper surface (i.e., the direction from the split electrode 18X− toward the split electrode 18X+), and the angle (azimuth angle) between the operation direction H1 of the slide operation and the reference azimuth H0 is defined as θ. In this case, the azimuth angle θ is given by Equation 1.

θ=arctan ((C(Y+)−C(Y−))/(C(X+)−C(X−)) Equation 1

That is, the operation direction H1 is a direction anticlockwise rotated by the azimuth angle θ with reference to the reference azimuth H0. The external control circuit detects the capacitances C (X+), C (X−), C (Y+), and C (Y−) of the split electrodes 18X+, 18X−, 18Y+, and 18Y− from the output signal of the connector 4, obtains the azimuth angle θ using Equation 1 from the detection result, and obtains the operation direction H1 from this azimuth angle.

### Operation for Inputting Second-Step Slide Operation

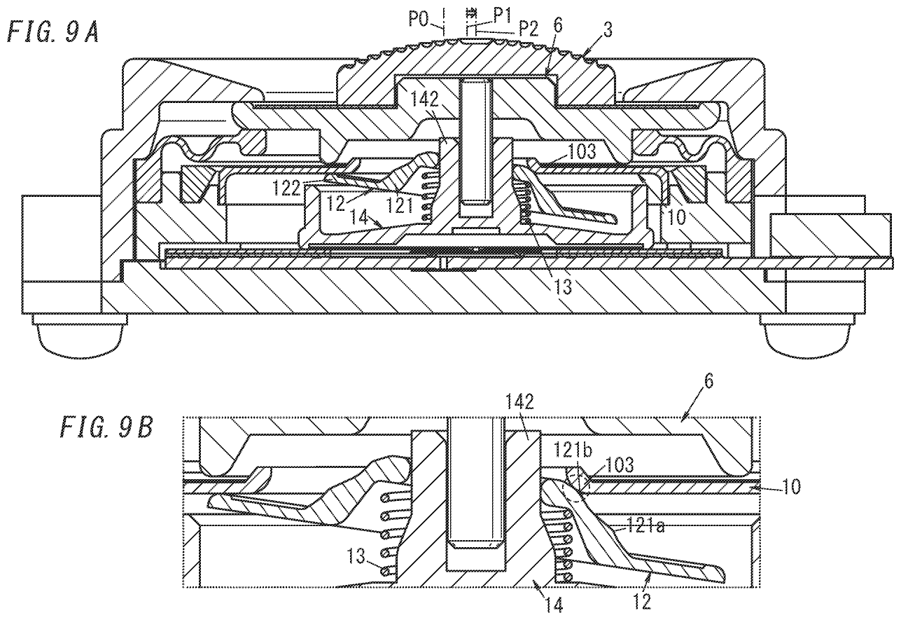

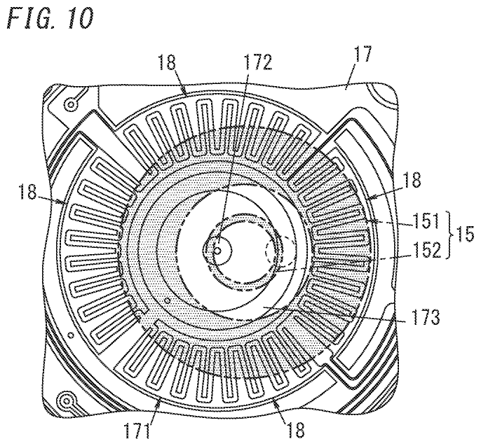

Next, referring to FIGS. 9A, 9B, and 10, operation when the second-step slide operation is input to the operation knob 3 will be described. The second-step slide operation is an operation of slidably moving the operation knob 3 from the first detection position P1 to a second detection position P2.

As shown in FIG. 9A, a further slide operation is given to the operation knob 3, and thereby, the operation knob 3 moves the operation knob 3 from the first detection position P1 to the second detection position P2, and along with this movement, the cam part 121 of the click cam 12 further moves to the back of the cover plate 10.

At this time, as shown in FIG. 9B, the contacting portion 103 of the cover plate 10 slides on the cam surface of the cam part 121 and is disposed at a position after the contacting portion 103 climbs over the second click ridge 121b. The contact part 103 increases the operation resistance against the slide operation until the contact part 102 climbs over the second click ridge 121b, and once the contact part 103 climbs over the second click ridge 121b, the contact part 103 then reduces the operation resistance. Due to a change in increasing/reducing the operation resistance, a sense of click is generated by the operation knob 3. Thus, in response to the slide operation of sliding the operation knob 3 from the first detection position P1 to the second detection position P2 (i.e., when the state of the moving electrode 15 changes from the second non-contact state to the second contact state as described later), a sense of click is generated in synchronization with the operation.

Further, as shown in FIG. 10, a further slide operation is given to the operation knob 3, and thereby, the operation knob 3 is slidably moved from the first detection position P1 to the second detection position P2, which brings the terminal 152 of the moving electrode 15 into contact with the switching electrode 173. That is, the state of the terminal 152 changes from a state of not being in contact with the switching electrode 173 (second non-contact state) to a state of being in contact with the switching electrode 173 (second contact state). After the state of the moving electrode 15 changes from the second non-contact state to the second contact state, the terminal 152 is still in contact with the reference electrode 172. That is, the terminal 152 is in the first contact state. The external control circuit connected to the connector 4 detects that the state of the moving electrode 15 has been changed from the second non-contact state to the second contact state, and thereby detecting that a further slide operation has been given to the operation knob 3 and the operation knob 3 has thus been slidably moved from the first detection position P1 to the second detection position P2 (that the second-step slide operation has been input to the operation knob 3).

Note that the external control circuit detects that the state of the moving electrode 15 has changed from the second non-contact state to the second contact state (the second-step slide operation has been input to the operation knob 3) as described below. That is, the external control circuit keeps the potential of the reference electrode 172 at a reference potential and detects the potential of the switching electrode 173 via the connector 4. In a state where the terminal 152 of the moving electrode 15 is not in contact with the switching electrode 173 (second non-contact state), the potential of the switching electrode 173 enters a floating state where the potential thereof is independent. However, in a state where the terminal 152 is in contact with the switching electrode 173 (second contact state), the terminal 152 is also in contact with the reference electrode 172. Therefore, the switching electrode 173 is in electrical conduction with the reference electrode 172 via the terminal 152. Since the reference electrode 172 is kept at the reference potential via the connector 4 as described above, the potential of the switching electrode 173 changes from the floating state to the reference potential. The external control circuit detects this change, thereby detecting that the state of the moving electrode 15 has changed from the second non-contact state to the second contact state.

Note that after a slide operation has been given and the operation knob 3 has thus been moved to the first detection position P1 or to the second detection position P2, the operation given to the operation knob 3 may be released, and in this case, the operation knob 3 (and thus, the moving electrode 15) autonomously returns to the reference position (P0) by being urged by the return spring 13.

### Supplementary Explanation of First Detection Position and Second Detection Position of Operation Knob

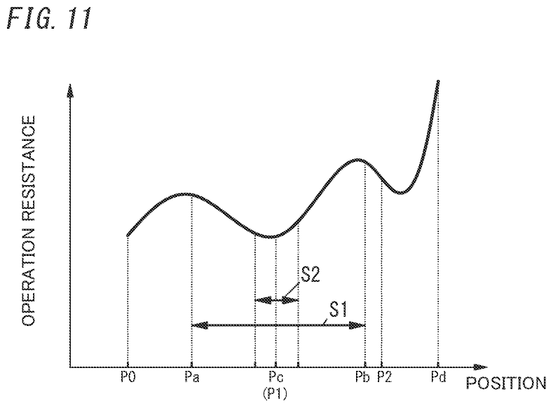

Next, referring to FIG. 11, the first detection position P1 (i.e., the position of the operation knob 3 when the first-step slide operation given to the operation knob 3 is detected) and the second detection position P2 (i.e., the position of the operation knob 3 when the second-step slide operation given to the operation knob 3 is detected) will be supplementarily described.

In FIG. 11, the horizontal axis represents the position of the operation knob 3, and the vertical axis represents the operation resistance of the operation knob 3. On the horizontal axis of FIG. 11, positions Pa and Pb are positions of the operating knob 3 when the contacting portion 103 of the cover plate 10 is positioned at the apexes of the first click ridge 121a and the second click ridge 121b, respectively. Position Pc corresponds to a trough between the two click ridges 121a and 121b and is a position at which the operation resistance of the operation knob 3 is minimum. Position Pd is a limit position of the range of movement of the operation knob 3.

As shown in FIG. 11, the operation resistance of the operation knob 3 increases while the operation knob 3 moves from the reference position P0 to the position Pa, and the operation resistance of the operation knob 3 decreases while the operation knob 3 moves from the position Pa to the position Pc. Further, the operation resistance of the operation knob 3 increases while the operation knob 3 moves from the position Pc to the position Pb, the operation resistance of the operation knob 3 decreases when the operation knob 3 further moves from the position Pb, and the operation resistance of the operation knob 3 increases when the operation knob 3 approaches the position Pc, which is the limit position. That is, when the operation knob 3 moves and climbs over the peak of the position Pa, a sense of click is generated by the operation knob 3. Moreover, when the operation knob 3 moves and climbs over the peak of the position Pb, a sense of click is generated by the operation knob 3.

In the present embodiment, the first detection position P1 is set to, for example, the position Pc in order to synchronize with a sense of click generated by the operation knob 3. The first detected position P1 may be set to any position within a scope S1 between the positions Pa and Pb, and the first detected position P1 is preferably set to be within a scope S2 before and after the position Pc. In the present embodiment, the second detection position P2 is also set to, for example, a position after the contacting portion 103 climbs over the position Pb in order to synchronize with the sense of click generated by the operation knob 3, but the second detection position P2 may be set to the position Pb.

### 1-4. Major Effects

The input device 1 according to the present embodiment includes the fixed electrode 171, the reference electrode 172, the operating knob 3, and the moving electrode 15. The fixed electrode 171 and the reference electrode 172 are provided on the sensor substrate 17. The operating knob 3 is movable relative to the sensor substrate 17. The moving electrode 15 faces the fixed electrode 171 and moves together with the operation knob 3. The moving electrode 15 is configured to move together with the operation knob 3 to enter either a connected state of being electrically connected to the reference electrode 172 or a non-connected state of not being electrically connected to the reference electrode 172.

With this configuration, when the state of the moving electrode 15 changes from the non-connected state to the connected state, the potential of the moving electrode 15 changes from the floating state to the potential of the reference electrode 172. This change changes the capacitance of the fixed electrode 171. This change enables more accurate detection of movement of the moving electrode 15 (i.e., input of the first stage operation to the operation knob 3).

### 1-5. Variations of First Embodiment

### First Variation

In the following description, parts different from those of Embodiment 1 are mainly described, and the same parts as those of Embodiment 1 are denoted by the same reference signs, and the description thereof is omitted in some cases.

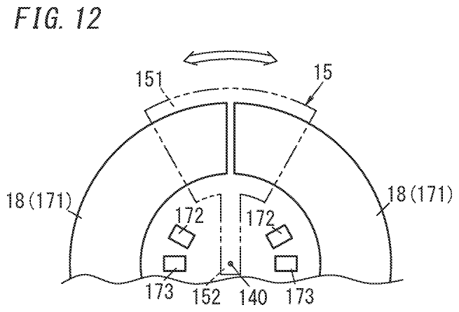

In the first embodiment, a slide operation is given to the operation knob 3, but a rotation operation may be given to the operating knob 3. In this case, the moving electrode 15 includes a moving electrode body 151 having a fan shape and a terminal 152 having a rod shape as shown in FIG. 12. The terminal 152 is connected to the moving electrode body 151 of the moving electrode 15. The moving electrode 15 is disposed on the rear surface of a mover 14 such that one end of the terminal 152 is positioned at the center 14c of the rear surface of the mover 14 and the moving electrode body 151 is disposed on the fixed electrode 171.

In the example shown in FIG. 12, the fixed electrode 171 includes two split electrodes 18. In this variation, each split electrode 18 includes one reference electrode 172 and one switching electrode 173. In each split electrode 18, the reference electrode 172 and the switching electrode 173 are aligned along an inner circumferential end of the split electrode 18 on an inner circumferential side of the split electrode 18. The switching electrode 173 is farther away from the reference position of the moving electrode 15 (i.e., the position of the moving electrode 15 shown in FIG. 12) than the reference electrode 172 is. Thus, when the moving electrode 15 is rotated from the reference position, the moving electrode 15 first comes into contact with the reference electrode 172 and then comes into contact with the switching electrode 173.

Also in this variation, in response to the rotation of the moving electrode 15 along with the rotation of the operation knob 3, the terminal 152 first comes into contact with the reference electrode 172 and then comes into contact with the switching electrode 173 in a similar manner to the first embodiment. These contacts are detected, and thereby, a first rotation operation and a second rotation operation are detected. Further, the capacitance of each split electrode 18 changes depending on the relative arrangement of the moving electrode body 151 and the split electrode 18 (the size of the area of the split electrode 18 overlapping the moving electrode body 151), and from the capacitance of each split electrode 18, the rotation amount of the operation knob 3 is detected.

Note that in the present variation, each split electrode 18 may include a drive electrode and a reception electrode as in the first embodiment or may be simply one-sided electrode.

### 2. Second Embodiment

In the following description, parts different from those of Embodiment 1 are mainly described, and the same parts as those of Embodiment 1 are denoted by the same reference signs, and the description thereof is omitted in some cases.

The present embodiment is different from the first embodiment in the mechanism of bringing a moving electrode 15 into, and out of, electrical contact with a reference electrode 172. An example is described below in which only the first stage operation can be input to an operation knob 3.

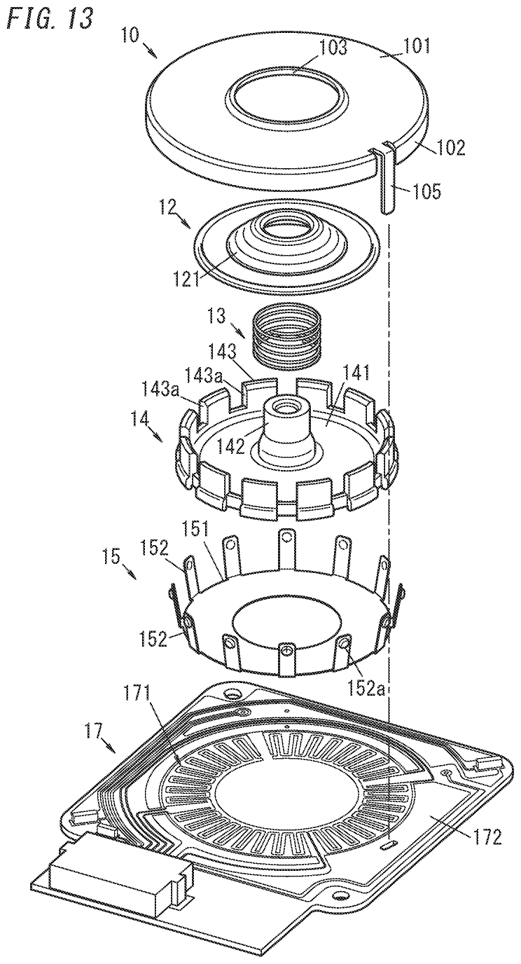

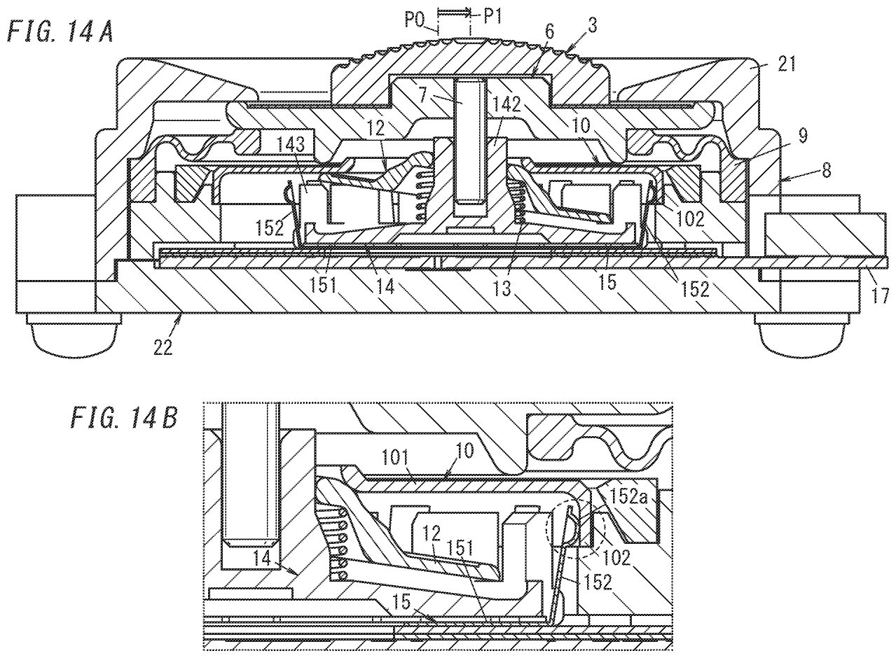

As shown in FIGS. 13 and 14A, the moving electrode 15 of this embodiment includes a moving electrode body 151 and a plurality of terminals 152. The moving electrode body 151 has a circularly annular plate shape.

Each of the plurality of terminals 152 is formed like, for example, a leaf spring having a strip shape. The plurality of terminals 152 rise frontward from an outer circumferential edge of the moving electrode body 151 and are tilted to an outer circumferential side of the moving electrode body 151. The plurality of terminals 152 are arranged at intervals in the circumferential direction at the outer circumferential edge of the moving electrode body 151. The plurality of terminals 152 have outer surfaces having tip ends provided with protrusions 152a which are to be brought into contact with a cover plate 10.

A mover 14 of the present embodiment corresponds to the mover 14 of the first embodiment and further has a plurality of cut-outs 143a formed in a peripheral wall 143. The plurality of cut-outs 143a can house the plurality of terminals 152 of the moving electrode 15. The moving electrode body 151 of the moving electrode 15 is provided on a rear surface of the mover 14 (see FIG. 14A). In this state, the plurality of terminals 152 are disposed to protrude from an inner side of the respective cut-outs 143a formed in the peripheral wall 143 of the mover 14 to an outer circumferential side of the peripheral wall 143.

The cover plate 10 of the present embodiment corresponds to the cover plate 10 of the first embodiment and further includes a connection terminal 105 for electrically connecting the cover plate 10 and the reference electrode 172 of a sensor substrate 17 to each other. The connection terminal 105 protrudes backward from a circumferential end of a substrate part 101 and is connected to the reference electrode 172 of the sensor substrate 17. The cover plate 10 of the present embodiment is made of metal in a similar manner to the cover plate 10 of the first embodiment.

The sensor substrate 17 of the present embodiment corresponds to the sensor substrate 17 of the first embodiment, from which the switching electrode 173 is omitted and in which the reference electrode 172 is disposed on an outer circumferential side of the fixed electrode 171 (see FIG. 14A). The reference electrode 172 of the present embodiment is connected to the connection terminal 105 of the cover plate 10 and is connected to a reference potential by an external control circuit via a connector 4.

In the present embodiment, components (i.e., a housing 2, an operation knob 3, a slider 6, a shaft 7, a rubber mat 8, a light guide 9, a frame 11, a click cam 12, a return spring 13, a dielectric film 16, and the like) other than the moving electrode 15, the mover 14, the cover plate 10, and the sensor substrate 17 which are described above are the same as those in the first embodiment.

In the present embodiment, in the standby state of the operation knob 3 (i.e., the state in which the operation knob 3 is positioned at the reference position P0), tip ends of the respective terminals 152 of the moving electrode 15 are disposed on an inner side of the peripheral wall 143 of the cover plate 10 so as to be separated from the cover plate 10. Along with the slide operation of sliding the operation knob 3 from the reference position P0 to the first detection position P1 (see FIG. 14A), the mover 14 moves in the same direction as the operation knob 3. Due to this movement, the protrusion 152a of any one terminal 152 of the plurality of terminals 152 comes into contact with an inner circumferential surface of the peripheral wall 102 of the cover plate 10 (see FIG. 14B). Due to this contact, the moving electrode body 151 is electrically connected to the reference electrode 172 of the sensor substrate 17 via the terminal 152 and the cover plate 10. Based on this connection, input of the first-step slide operation to the operation knob 3 is detected in a similar manner to the first embodiment.

The present embodiment can also obtain the same effect as the main effect of the first embodiment.

### Variations of Second Embodiment

### First Variation

In the following description, parts different from those of the second embodiment are mainly described, and the same parts as those of the second embodiment are denoted by the same reference signs, and the description thereof is omitted in some cases.

In the second embodiment, the plurality of terminals 152 of the moving electrode 15 contact and separate from the cover plate 10. In contrast, in the present variation, the plurality of terminals 152 of the moving electrode 15 contact and separate from the click cam 12.

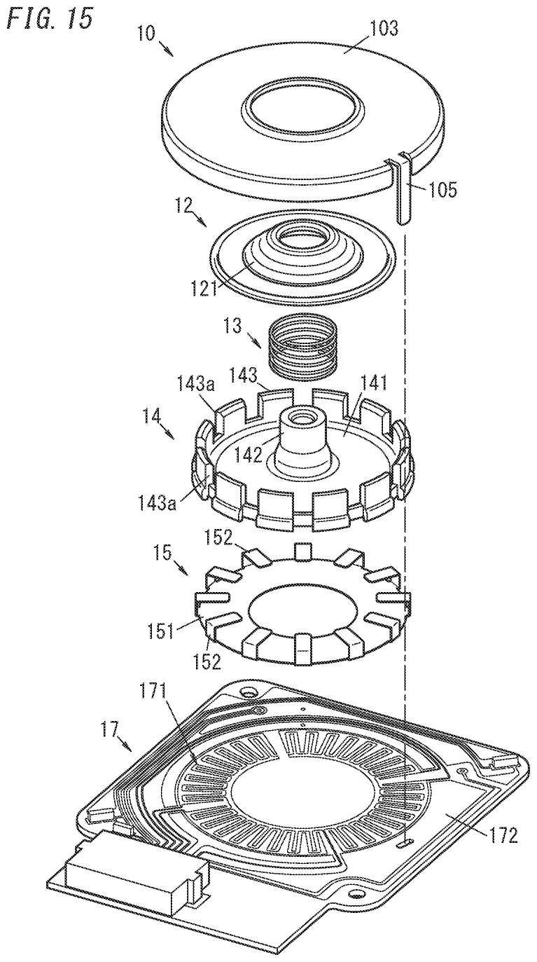

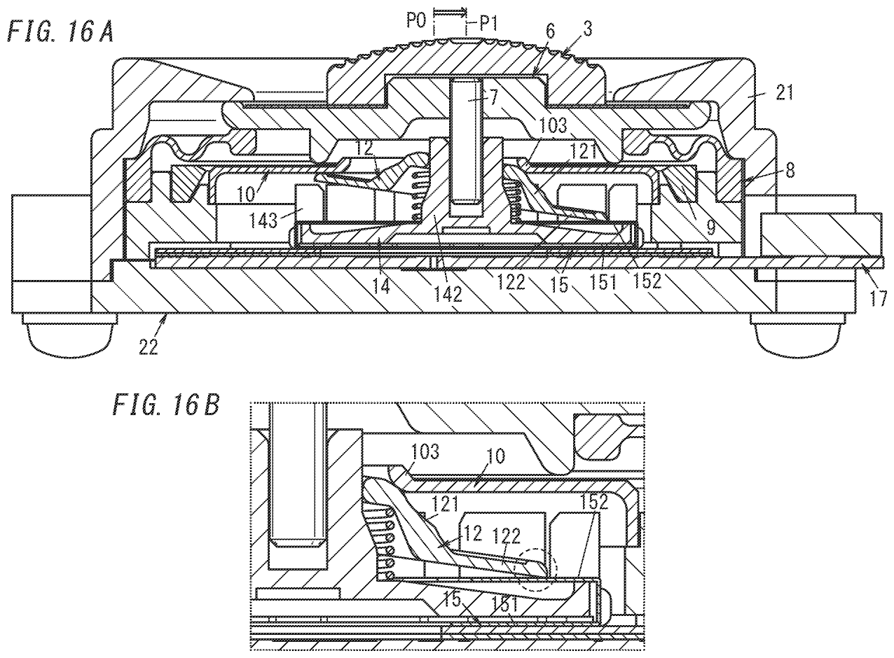

As shown in FIG. 15, the moving electrode 15 of the present variation corresponds to the moving electrode 15 of the second embodiment but the terminals 152 are different in terms of the shape. More specifically, each of the terminals 152 of the present embodiment rises frontward from the outer circumferential edge of a moving electrode body 151 and is bent inward at an intermediate position in the longitudinal direction thereof. As a result, when the moving electrode body 151 is provided on the rear surface of the mover 14, the respective terminals 152 are in the plurality of cut-outs 143a of the peripheral wall 143 of the mover 14. In this state, the respective terminals 152 protrude inward with respect to the peripheral wall 143 (see FIG. 16A). In the present variation, the terminals 152 do not have the protrusions 152a described in the second embodiment but may have the protrusions 152a.

In the present embodiment, in the standby state of the operation knob 3 (i.e., the state in which the operation knob 3 is positioned at the reference position P0), the terminals 152 of the moving electrode 15 are disposed to be separated from the click cam 12 on the rear side of the click cam 12. When a slide operation is given and the operation knob 3 is thus slidably moved from the reference position P0 to the first detection position P1 (see FIG. 16A), the click cam 12 is tilted with respect to the boss 142 of the mover 14 and moves to the back of the cover plate 10. At this time, the contact part 103 of the cover plate 10 moves while sliding (i.e., while contacting) on the cam surface of the click cam 12 (the outer circumferential surface of the cam part 121) (see FIG. 16B). Furthermore, since the click cam 12 is tilted as described above, the outer circumferential edge part 122 of the click cam 12 comes into contact with any of the plurality of terminals 152 of the moving electrode 15 (see FIG. 16B).

Thus, the cam surface of the click cam 12 and the contact part 103 of the cover plate 10 come into contact with each other, and the outer circumferential edge part 122 of the click cam 12 and the terminal 152 of the moving electrode 15 come into contact with each other. Thus, the moving electrode body 151 of the moving electrode 15 is connected to the reference electrode 172 of the sensor substrate 17 via the terminal 152, the click cam 12, and the cover plate 10. Based on this connection, input of the first-step slide operation to the operation knob 3 is detected in a similar manner to the first embodiment.

The present embodiment can also obtain the same effect as the main effect of the first embodiment.

### Other Variations

The first and second embodiments and their variations may be implemented in combination.

### 3. Summary

An input device (1) of a first aspect includes a fixed electrode (171), a reference electrode (172), an operation part (3), and a moving electrode (15). The fixed electrode (171) and the reference electrode (172) are separate from each other on a substrate (17). The operation part (3) is movable with respect to the substrate (17). The moving electrode (15) faces the fixed electrode (171) and is configured to move together with the operation part (3). The moving electrode (15) moves together with the operation part (3) to enter either a connected state of being electrically connected to the reference electrode (172) or a non-connected state of not being electrically connected to the reference electrode (172).

With this configuration, when the state of the moving electrode (15) changes from the non-connected state to the connected state, the potential of the moving electrode (15) changes from a floating state to the potential of the reference electrode (172). This change changes the capacitance of the fixed electrode (171). This change enables more accurate detection of movement of the moving electrode (15) (i.e., input of the first stage operation to the operation knob (3)).

In an input device (1) of a second aspect referring to the first aspect, the fixed electrode (171) has capacitance which changes depending on a relative arrangement of the fixed electrode (171) and the moving electrode (15).

With this configuration, the movement of the moving electrode (15) (and thus, the movement of the operation part (3)) is more accurately detected based on the capacitance of the fixed electrode (171).

In an input device (1) of a third aspect referring to the first or second aspect, the moving electrode (15) is movable along the substrate (17).

With this configuration, the operation part (3) is operable along the substrate (17). That is, a slide operation of the operation part (3) is possible.

In an input device (1) of a fourth aspect referring to any one of the first to third aspects, the moving electrode (15) is configured to, when an operation given to the operation part (3) is released, autonomously return to a reference position (P0).

With this configuration, the operation part (3) autonomously returns to the reference position (P0) when no operation is given to the operation part (3).

In an input device (1) of a fifth aspect referring to the fourth aspect, the moving electrode (15) is in the non-connected state when the moving electrode (15) is at the reference position (P0).

With this configuration, the reference position (P0) is a dead zone in which the movement of the moving electrode (15) is not detected.

In an input device (1) of a sixth aspect referring to any one of the first to fourth aspects, the moving electrode (15) is linearly movable along the substrate (17).

With this configuration, the operation part (3) is linearly operable along the substrate (17).

In an input device (1) of a seventh aspect referring to any one of the first to sixth aspects, the moving electrode (15) is movable from a current position in any direction along the substrate (17).

With this configuration, the operation part (3) is operable from the current position in any direction along the substrate (17).

In an input device (1) of an eighth aspect referring to any one of the first to seventh aspects, the fixed electrode (171) includes a drive electrode (181) and a receiving electrode (182). The drive electrode 181 has a plurality of first comb teeth 181b. The receiving electrode (182) has a plurality of second comb teeth (182b). Each of the plurality of first comb teeth (181b) is disposed between the plurality of second comb teeth (182b).

With this configuration, the capacitance of the fixed electrode (171) is constituted by capacitance between the drive electrode (181) and the receiving electrode (182). Thus, the capacitance of the fixed electrode (171) is suppressed from being externally influenced. As a result, the movement of the moving electrode (15) (and thus, the movement of the operation part (3)) is more accurately detected.

In an input device (1) of a ninth aspect referring to any one of the first to eighth aspects, the fixed electrode (171) includes four split electrodes (18) arranged in a ring shape.

With this configuration, the direction of movement (i.e., the operation direction of the operation part (3)) (H1) of the moving electrode (15) can be easily obtained.

An input device (1) of a tenth aspect referring to any one of the first to ninth aspects further includes a first click sense generator (10, 12) configured to cause the operation part (3) to generate a sense of click when a state of the moving electrode (15) changes from the non-connected state to the connected state.

With this configuration, a sense provided in response to the operation given to the operation part (3) informs an operator of a change of the state of the moving electrode (15) from the non-connected state to the connected state.

An input device (1) of an eleventh aspect referring to any one of the first to tenth aspects further includes a switching electrode (173) on the substrate (17). The connected state is defined as a first connected state, and the non-connected state is defined as a first non-connected state. The moving electrode (15) moves together with the operation part (3) to enter either a second connected state of being electrically connected to the switching electrode (173) or a second non-connected state of not being electrically connected to the switching electrode (173).

With this configuration, when the state of the moving electrode (15) changes from the second non-connected state to the second connected state, the potential of the switching electrode (173) changes. This change enables more secure detection of movement of the moving electrode (15) (i.e., input of the second stage operation to the operation knob (3)).

In an input device (1) of a twelfth aspect referring to the eleventh aspect, the switching electrode (173) has an annular shape concentric with the reference electrode (172).

With this configuration, input of the second stage operation to the operation part (3) is more accurately detected also when the operation part (3) is moved to any direction around the reference electrode (172).

In an input device (1) of a thirteenth aspect referring to the eleventh or twelfth aspect, the input device (1) further includes a second click sense generator (10, 12) configured to cause the moving electrode (15) to generate a sense of click when the state of the moving electrode (15) changes from the second non-connected state to the second connected state.

With this configuration, a sense provided in response to the operation given to the operation part (3) informs an operator of a change of a state of the moving electrode (15) from the second non-connected state to the second connected state.

### REFERENCE SIGNS LIST

1 Input Device

3 Operation Knob (Operation Part)

10 Cover Plate (Click Sense Generator, First and Second Click Sense Generator)

12 Click Cam (Click Sense Generator, First and Second Click Sense Generator)

15 Moving electrode

18 Split Electrode

17 Sensor Substrate (Substrate)

171 Fixed Electrode

172 Reference Electrode

173 Switching Electrode

181 Drive Electrode

181b First Comb Teeth

182 Receiving Electrode

182b Second Comb Teeth

H1 Operation Direction

P0 Reference Position

1. An input apparatus comprising:
a fixed electrode and a reference electrode separate from each other on a substrate;
an operation part movable with respect to the substrate; and
a moving electrode facing the fixed electrode and configured to move together with the operation part,
the moving electrode moving together with the operation part to enter either a connected state of being electrically connected to the reference electrode or a non-connected state of not being electrically connected to the reference electrode.

2. The input apparatus of claim 1, wherein
the fixed electrode has capacitance which changes depending on a relative arrangement of the fixed electrode and the moving electrode.

3. The input apparatus of claim 1, wherein
the moving electrode is movable along the substrate.

4. The input apparatus of claim 1, wherein
the moving electrode is configured to, when an operation given to the operation part is released, autonomously return to a reference position which is preset.

5. The input apparatus of claim 4, wherein
the moving electrode is in the non-connected state when the moving electrode is at the reference position.

6. The input apparatus of claim 1, wherein
the moving electrode is linearly movable along the substrate.

7. The input apparatus of claim 1, wherein
the moving electrode is movable from a current position in any direction along the substrate.

8. The input apparatus of claim 1, wherein
the fixed electrode includes
a drive electrode having a plurality of first comb teeth and
a receiving electrode having a plurality of second comb teeth, and each of the plurality of first comb teeth is disposed between the plurality of second comb teeth.

9. The input apparatus of claim 1, wherein
the fixed electrode includes four split electrodes arranged in a ring shape.

10. The input apparatus of claim 1, further comprising a first click sense generator configured to cause the operation part to generate a sense of click when a state of the moving electrode changes from the non-connected state to the connected state.

11. The input apparatus of claim 1, further comprising a switching electrode on the substrate, wherein
the connected state is defined as a first connected state, and the non-connected state is defined as a first non-connected state, and
the moving electrode moves together with the operation part to enter either a second connected state of being electrically connected to the switching electrode or a second non-connected state of not being electrically connected to the switching electrode.

12. The input apparatus of claim 11, wherein
the switching electrode has an annular shape concentric with the reference electrode.

13. The input apparatus of claim 11, wherein
the input device further includes a second click sense provider configured to cause the moving electrode to generate a sense of click when a state of the moving electrode changes from the second non-connected state to the second connected state.
